(19) United States
(12) Patent Application Publication
(10) Pub. No.: US 2012/0050075 A1
(43) Pub. Date: Mar. 1, 2012

(54) RETRACTABLE DEVICE

(76) Inventor: Peter C. Salmon, Mountain View, CA (US)

(21) Appl. No.: 13/215,921

(22) Filed: Aug. 23, 2011

Related U.S. Application Data
(60) Provisional application No. 61/376,441, filed on Aug. 24, 2010.

(51) Int. Cl. H03K 17/94; H05K 7/00; G06F 1/16

(52) U.S. Cl. 341/20; 361/679.21; 361/679.01

(57) ABSTRACT

A device includes a processor and a memory coupled to the processor. The memory is encoded with instructions that are executable by the processor to provide content signals. The device also includes a display screen extendable to present an extended portion comprising display pixels configured to display content using the content signals. Extension of the display screen imposes a compound shape on the extended portion of the display screen characterized by a central region and a peripheral angled edge region.

### CROSS-REFERENCES TO RELATED APPLICATIONS

This application claims priority to U.S. Provisional Patent Application No. 61/376,441, filed on Aug. 24, 2010, entitled “Retractable Device,” the disclosure of which is hereby incorporated by reference in its entirety for all purposes.

### BACKGROUND OF THE INVENTION

The size of electronic devices ranges from the very small to the very large. Gaming devices, portable data assistants (PDAs) and other portable computing devices, laptops, cell phone, smart phones, video players, music players, medical devices, and numerous other types of electronic devices are typically provided in sizes and shapes that are convenient for a user to hold, carry, and transport, for example, by being able to fit within a user's purse or pocket. For example, portable electronic devices are beginning to be used as personal computing platforms, combining computational power and communication capabilities with user convenience in a compact form. Typically such devices include a display used to present pertinent information to the user and, in some cases, the display surface can also be used as a touch sensitive input device. A popular form of such a portable electronic device fits comfortably in a shirt pocket.

Despite the progress made in electronic devices, there is a need in the art for improved methods and systems for display devices.

### SUMMARY OF THE INVENTION

The present invention relates generally to electronic devices. More specifically, the present invention relates to methods and systems for electronic devices having retractable elements. Particular embodiments of the present invention enable increased display size while retaining portability. Merely by way of example, the invention has been applied to electronic devices having screens or other display elements for displaying images, keyboard elements, sound producing elements, heating/cooling elements, and/or other elements that are retractable.

According to an embodiment of the present invention, a device is provided. The device includes a processor and a memory coupled to the processor. The memory is encoded with instructions that are executable by the processor to provide content signals. The device also includes a display screen extendable to present an extended portion comprising display pixels configured to display content using the content signals. Extension of the display screen imposes a compound shape on the extended portion of the display screen characterized by a central region and a peripheral angled edge region.

According to another embodiment of the present invention, a device is provided that includes an enclosure and an element extendable from the enclosure to present an extended portion comprising transducers. The extended portion is characterized by a plurality of radii of curvature in some embodiments. In other embodiments, the extended portion is characterized by one or more radii of curvature.

According to yet another embodiment of the present invention, a method of operating a retractable electronic device is provided. The method includes extending an element from within an enclosure to present an extended portion comprising transducers outside of the enclosure and activating the transducers to output content via a surface of the extended portion of the element. The method also includes retracting the element to a compact form within the enclosure.

According to an embodiment of the present invention, a device having a processor coupled to a memory encoded with instructions that are executable by the processor to provide content signals is provided. The device further has a display screen extendable to present an extended portion comprising display pixels configured to display content using the content signals. Extension of the display screen imposes an arcuate cross-sectional shape on the extended portion of the display screen, for example, to impose stiffness, rigidity, strength, or otherwise support the extended portion. The arcuate cross-sectional shape may produce uniform stiffness throughout the extended portion of the display screen. In addition to display pixels, the extended portion may have touch sensors for receiving touch input on a surface of the extended portion. The exemplary device may include an enclosure with a curved slot from which the extended portion extends while extended. The arcuate cross-sectional shape may be imposed by the curved slot in the enclosure. The enclosure may secure the display screen when retracted such that the arcuate cross-sectional shape is not imposed on the display screen while secured within the enclosure.

According to another embodiment of the present invention, a device is provided that includes an element extendable to present an extended portion comprising transducers and an enclosure comprising a curved slot through which the element is extended and retracted. An arcuate cross-sectional shape is imposed on the extended portion by the curved slot in the enclosure, but the arcuate cross-sectional shape is not imposed while the element is secured within the enclosure. The transducers may convert electrical signals originating from a processor to display a pixel-based electronic image, provide a screen for projected light images, convert touch input on a surface of the extended portion to signals provided to a processor, produce sound, produce heat, or provide a cooling function, as examples.

According to a specific embodiment of the present invention, a method is provided that includes extending an element from within an enclosure to present an extended portion comprising transducers outside of the enclosure. The element is extended through a curved slot in the enclosure, such that the curved slot imposes an arcuate cross-sectional shape on the extended portion. The arcuate cross-sectional shape is not imposed while the element is secured within the enclosure. The exemplary method further comprises activating the transducers to output content or receive input via a surface of the extended portion of the element and retracting the element to a compact form within the enclosure.

According to another specific embodiment of the present invention, an electronic device having a retractable element is provided. The retractable element has an extended form and a retracted form. The extended form may be stiffened by imposing an arcuate shape. The arcuate shape may be curved or angled, over the entire retractable element or limited to edge regions or other portions. The retractable element may comprise plastic and/or metallic material, and the arcuate shape may be imposed in molds or tooling by combinations of heat and pressure, casting, cold forming, or the like.

According to another embodiment of the present invention, a device is provided. The device includes a processor and a memory coupled to the processor. The memory is encoded with instructions that are executable by the processor to provide content signals. The device also includes a display screen extendable to present an extended portion comprising display pixels configured to display content using the content signals. Extension of the display screen imposes an arcuate cross-sectional shape on the extended portion of the display screen. The arcuate cross-sectional shape imposed on the extended portion of the display screen can produce uniform stiffness throughout the extended portion of the display screen. The display screen can include a polymeric material having a thickness between 5 μm and 250 μm or a metallic material. In some embodiments, the extended portion further comprises touch sensors for receiving touch input on a surface of the extended portion. The device can include an enclosure having a curved slot from which the extended portion extends while extended. A radius of curvature of the curved slot is between 0.5 inch and 20 inches. The display screen is secured within the enclosure in a retracted position in which the arcuate cross-sectional shape is not imposed on the display screen while secured within the enclosure. The device can also include a tab accessible for extending the display screen from the enclosure. Moreover, the device can include a crank, wherein rotation of the crank rolls the display screen within the enclosure.

In an embodiment, each of the display pixels comprises display circuits coupled to the processor that are operable to emit or reflect light. The display circuits can be coupled to the processor using wires or conductive traces. In other embodiments, the device can include an interface chip operable to provide for wireless communications under the control of the processor. When fully extended, the extended portion can have a length to width ratio between 0.1 and 10. The device can additionally include at least one of a motor or a spring configured to retract the display screen.

Numerous benefits are achieved by way of the present invention over conventional techniques. For example, embodiments of the present invention provide solutions to conventional devices in which the degree of portability is usually accompanied by a small-sized display that may be considered ill-suited for some applications, such as, but not limited to watching video, viewing or editing large documents, reviewing or creating emails, and performing spreadsheet calculations. Utilizing embodiments of the present invention, large display areas are provided as suitable for the above applications.

These and other embodiments of the invention along with many of its advantages and features are described in more detail in conjunction with the text below and attached figures.

### BRIEF DESCRIPTION OF THE DRAWINGS

FIG. 1 is a top view of a device having a flexible, retractable element in extended form.

FIG. 2 is an expanded cross-sectional view of a portion of the device of FIG. 1, in retracted form.

FIG. 3 is an end view of the mechanism shown in FIG. 2, corresponding to “View A”.

FIG. 4 is a top schematic view of the flexible, retractable element of the device of FIG. 1.

FIG. 5 is a cross-sectional view of the shaft assembly of the device of FIG. 1.

FIG. 6 is an expanded cross-sectional view of a retractable mechanism showing placement of a wireless chip for interfacing between a host processor and display circuits.

FIG. 7 is a cross-sectional view of an electronic device, including a rollable display.

FIG. 8 is a cross-sectional view of the formed shape of the flexible retractable element of the rollable display of FIG. 7.

FIG. 9 is a schematic diagram of the electronic device of FIG. 7 in refracted form.

FIG. 10 corresponds to section CC of FIG. 8, and illustrates angled side-edges.

FIG. 11 is a schematic top view of the flexible retractable element of the rollable display of FIG. 7, including a pixel display component.

FIG. 12 is an expanded view of a corner structure 112 of FIG. 11.

FIG. 13 is an expanded view of leading edge 116 of retractable element 71 of FIG. 11.

FIG. 14 is a simplified flowchart illustrating a method of operating a retractable electronic device according to an embodiment of the present invention.

### DETAILED DESCRIPTION OF SPECIFIC EMBODIMENTS

Electronic devices having screens or other display elements for displaying images, keyboard elements, sound producing elements, heating/cooling elements, and/or other elements that are retractable are disclosed. Such elements may extend and retract from a device by being extended to an elongated or extended form and then retracted to a retracted form, as a specific example, by being unwound from and then wound inside an enclosure. In embodiments in which the retractable element is wound, the retractable element comprises a flexible substrate. As examples, thin polymeric (plastic) materials, thin metal foils, and the like may be used in embodiments of the present invention. Some materials provided herein have a flexural modulus in the range of 0.5-10 GPa, although other materials with other characteristics may also be used.

In an embodiment, a flexible, retractable element of a device is stiffened when unwound or otherwise extended from the device because an arcuate (i.e., bowed) cross-sectional shape is imposed across the retractable element. If extended without any stiffening strategy, a flexible element would typically sag due to gravity and have other undesirable mechanical instabilities. However, an arcuate shape is imposed on the flexible, retractable substrate, providing adequate stiffness, for example, for providing a display and/or accepting touch inputs without substantially bending or deforming. The arcuate shape thus provides support and rigidity, for example, for a uniformly contoured and useable display screen. For example, adding curvature to a sheet of flexible material can create mechanical shell characteristics, causing it to carry loads through a combination of membrane response and bending response. Membrane response or “shell response” can increase stiffness for example in the way that the arcuate shape of shells such as arched panels, cylindrical pipes, and egg shells increase the stiffness of those objects that if otherwise shaped would bend or break more easily.

The flexible, retractable element may, but need not, include or otherwise use support strips or braces to provide additional support when extended. Omitting strips or braces may reduce the thickness, weight, or other attributes of a device. For example, a flexible element may be wound into a more compact retracted form by omitting strips or braces.

A flexible, retractable element may be used to provide one or more of a wide variety of features on a device. As examples, a flexible, retractable element may comprise transducers for various purposes, a screen for displaying pixel-based electronic images, a screen for projected light images, a keyboard, a touch-based input device, a sound producing device, and/or a heating or cooling device. A flexible, retractable element may provide or add multi-media capabilities to a device. For example, a smart phone device may include a flexible, retractable element that provides information to a user that is visual (e.g., via display pixels), aural (e.g., voice, music, or other audio), and/or tactile. In an embodiment in which the retractable elements provides a screen for projected light images in the extended position, the reflectivity of various portions of the element may be varied to provide a predetermined reflection profile that can be fixed for a period of time to display still images on a screen and change at a predetermined refresh rate as appropriate to the display of video images on a screen.

In one embodiment, a retractable display comprising display pixels on a flexible substrate is peripheral to a host electronic device, which may be a hand-held device. The display pixels are capable of emitting or reflecting light and have associated display circuits. In this example, a display pixel is a picture element representing one dot on the display screen. Communication between the host and the display circuits may employ wires or flexible circuit traces and/or wireless communications. A wired interface may employ the High Definition Multimedia Interface (“HDMI”) standard for example, or alternatively a variant of the Universal Serial Bus (“USB”) standard. Wireless communications may employ recent semiconductor chips developed for Near Field Communications (“NFC”), optimized for a short range such as a few centimeters. A device that includes a fixed, rigid screen may include a flexible, retractable element that provides a larger screen, for example, to display enhanced content when a user-selects a large-size display format option. Such a large size display can enable an improved user experience for watching movies, television, or the like, as well as for graphics-intensive applications such as video games, large spreadsheets, long threads of e-mail messages, and medical diagnostics, including X-ray analysis, for example.

A flexible, extendible element may comprise a metal foil and provide a heating or cooling function on a device. In one such device, a cooling surface or heat sink may be extended from the device in extended form if additional cooling is necessary and retracted into a smaller form when the cooling is not needed. Extending a cooling surface may be manually controlled or automatic, for example, based on a sensor detecting that cooling is required. A device with a flexible, retractable, cooling element may be employed by a soldier, for example, who may deploy the cooling element to cool an electronic equipment pack while in camp and retract the cooling element to enable a compact profile when on the move.

Various mechanisms may be used to extend and retract a flexible, retractable element. For example, a flexible, retractable element may be extended by a user pulling on a tab provided at an edge or a projecting portion of the element that is accessible while the element is retracted. Winding or otherwise retracting and unwinding or otherwise extending a flexible, retractable element may be accomplished using any combination of human fingers, a knurled knob, a hand crank, a spring, or a motor, as examples. In one example, human fingers apply torque for winding and unwinding to either a knurled knob or to a hand crank that winds a rollable retractable element into a compact wound state within an enclosure. Unwinding may additionally or alternatively be achieved by the user pulling on a tab. A spring may be used to store energy during unwinding, the energy returned during the winding operation to reduce the required torque. The spring may obviate the need for a motor to wind the device. Alternatively, a motor may be used to apply torque for winding or unwinding, in response to, for example, a user pressing a button on the device.

A larger display may be provided as a user option, to be deployed when preferred by the user, and having a convenient method for deploying the larger display and for storing it when done. This display can accomplish this function while not significantly compromising compactness, or portability such as the ability to carry the device in a shirt pocket. It is desirable that the retractable display be rugged enough to sustain many thousands of deployment cycles; also to sustain dropping on the floor or other surface without severe damage.

These illustrative examples are given to illustrate embodiments of the present invention and are not intended to limit the scope of the present invention. The following sections describe various additional embodiments and examples with reference to the drawings in which like numerals indicate like elements. It should be noted that the figures are only intended to facilitate the description of specific embodiments. They are not intended as an exhaustive description or as a limitation on the scope of the present invention. In addition, an aspect described in conjunction with a particular embodiment is not necessarily limited to that embodiment and may be practiced in other embodiments.

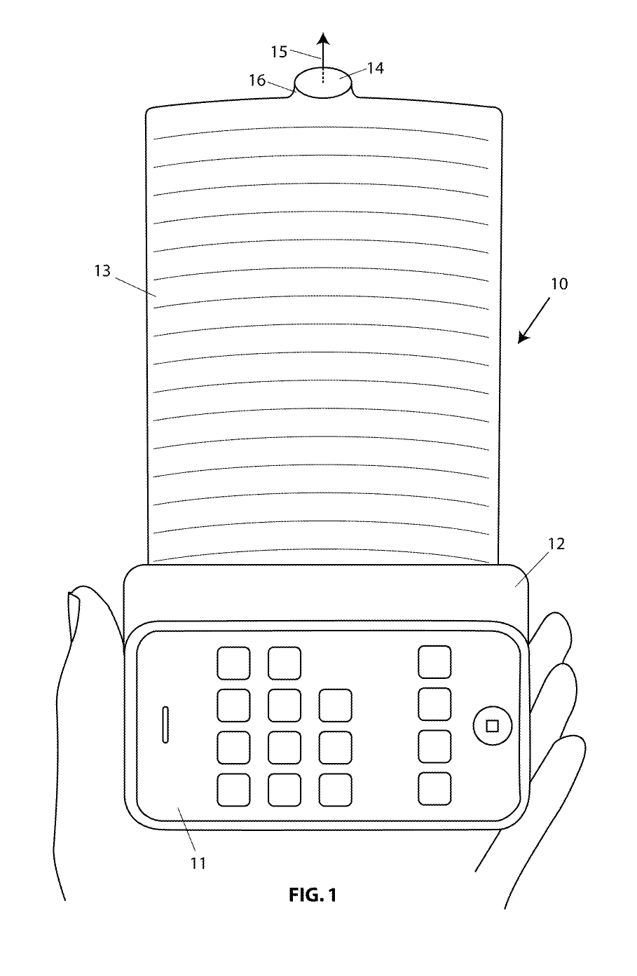

FIG. 1 is a top view of a device 10 having a flexible, retractable element 13 in extended form. The configuration depicted in FIG. 1 is referred to as in “extended form” because the retractable element 13 has an extended portion that has been extended from enclosure 12 in contrast to the retractable element being in a “retracted form” within enclosure 12 with no or only a portion of the retractable element 13 extending therefrom. Content can be displayed on the retractable element 13 in either a landscape or portrait orientation or both, and selection of display orientation may be controlled by software, based on device 10 orientation, based on user preferences, and/or based on user selection of display orientation.

The enclosure 12 in the example of FIG. 1 extends component 11, having the same approximate length and thickness dimensions. Enclosure 12 may be an integral part of component 11, permanently affixed to component 11, or removably affixed to component 11. Enclosure 11 provides space for storing the retractable element 13. In FIG. 1, the extended portion of the retractable element 13 has a curved characteristic, illustrated by the curved contour lines representing a concave shape viewed from above. Thus, the profile of retractable element 13 has an arcuate cross-sectional shape having a stiffening radius of curvature as described more fully below. As few as a few degrees of curvature may provide an arcuate cross-sectional shape on the extended portion of the retractable element 13 that is sufficient to sufficiently stiffen and/or stabilize the extended portion of the retractable element 13. In one example, considering tangent lines perpendicular to the long dimension of the retractable element 13, the tangent at the edge measures less than 20 degrees from the tangent at the center of the display. Various radius of curvature values may be used depending upon device characteristics and/or stiffness/stability requirements. For example, a radius of around 0.5 inches may be used for a small retractable element such as a small display attached to a headset while a radius of around 24 inches may be used for a large retractable element such as a display on an X-ray reader. In embodiments in which the retractable element 13 is a display, the curvature of the display may reduce glare from reflections and/or enhance privacy by shielding or reducing the view from side angles that correspond to potentially unwanted viewers. At the end of retractable element 13 is a pull tab 14 that can be gripped by a user and pulled in the direction of arrow 15 to deploy retractable element 13. Pull tab 14 is affixed to extended portion 16 of retractable element 13, and portion 16 may itself be used as a pull tab.

Retractable element 13 may be a display screen. Various display technologies are well suited to retractable displays. These include but are not limited to organic light emitting diode (“OLED”) displays and quantum dot displays (“QLEDs”). Some versions of these display technologies support high resolution pixel displays and are also fast enough to display video for movies and television, such as, active matrix (“AM”) displays, including AMOLED and AMQLED respectively. AMOLED and AMQLED displays may employ a single substrate that may be easier to wind around a small radius spool. A small radius may be useful for portable devices, for example, improving the ability of a device to fit easily in a user's pocket. Also, the substrate may be thin, of the order of 0.002 inches for example, providing lower bending forces than thicker substrates. The lower bending forces lead to a lower winding torque.

Multiple thin film layers may be deposited and patterned on the substrate to form a display screen. The thin film layers may include both organic and inorganic materials and combinations thereof. AM displays typically require a backplane comprising thin film transistors (TFTs) arranged to implement row-and-column addressing of individual display elements (pixels). The layers comprising the TFT backplane and the light-emitting or light-controlling elements may be thin, for example, of the order of 1 μm in thickness, and may have a flexible rather than a brittle characteristic so they can withstand many thousands of deployment cycles without cracking or fatigue problems.

Other display types may also be rollable, including liquid crystal displays (“LCDs”), and electrophoretic or “electronic paper” or “ePaper” reflective type displays. LCD displays are typically constructed on a plurality of substrates arranged in a stack. Typically these will include a diffuser, polarizers, color filters and a backlight for example. An ePaper display also typically requires a plurality of substrates in a stacked construction, which may make it more difficult to roll the display into a small radius enclosure for storage. Nonetheless, both LCD and ePaper displays may be adaptable to rollable versions, albeit with a larger radius than single-substrate devices in some embodiments. Reel-to-reel manufacturing methods are suitable for many display types with printed electronics methods of fabrication enabling substantially lowered production costs.

Retractable element 13 may comprise one or more of many suitable polymeric and/or other materials, including but not limited to various forms of polyethylene terephthalate (PET), polyethylene naphthalate (PEN), MYLAR, MELINEX, and multiple forms of polyimide (KAPTON, UPILEX, CR1). PET, PEN, MYLAR, MELINEX, KAPTON and UPILEX are thermo-elastic materials that can be heat formed by applying heat and pressure in a mold. CR1 is a clear polyimide available from Mantech Electronics (Pty) Ltd. that can be cast in a mold. Benzocyclobutene, BCB, is a polymeric resin used as a dielectric and can also be cast in a mold. Retractable element 13 may also comprise one or more of many suitable metallic materials, including but not limited to steel, spring steel, and stainless steel as examples. For good performance in an environment of repeated stress (during rolling and unrolling for example) the metallic materials may be “full hard”, such as full hard 302 or 304 stainless steel, which may be dual certified as AMS5906 and AMS5913 respectively. Advantages provided by metallic materials use in conjunction with retractable element 13 are lower creep and a reduced tendency to take on a set when stored in retracted form, particularly at high temperatures. The metallic materials may be formed by cold stamping, or by a drawing process as examples. Other advantages of metallic materials are an improved water barrier, since metals generally are substantially less water permeable than other materials, and moisture can adversely affect many electronic devices, OLED displays in particular. OLED and QLED displays are light-emitting, not requiring a backlight. ePaper displays are reflective, again not requiring a backlight. Liquid crystal displays employ electronic light shutters implemented using liquid crystals as cross-polarizable materials and typically require a backlight.

A further advantage of using a metallic material for the retractable element 13 may relate to integration of a pixel display substrate with a retractable element, the advantage relating to cold forming of the retractable element. For example, a pixel display substrate with a fully formed backplane and light emitting pixels may be produced by a first manufacturer. This display substrate may have high value, and further processing may degrade it, particularly processing at an elevated temperature. The retractable element 13 may be produced by a second manufacturer. For convenience and low cost relating to integration of the pixel display substrate of the first manufacturer with the retractable element of the second manufacturer, and to avoid degradation of the valuable display substrate, cold forming around the edges of retractable element 13 may be desirable. Cold forming may also be used advantageously for affixing the pixel display substrate to the retractable element, as will be further described below.

The retractable element 13 may, but need not, include or otherwise use support strips or braces (not shown) to provide additional support when extended. Omitting strips or braces may reduce the thickness, weight, or other attributes of a device. For example, a flexible element may be wound into a more compact retracted form by omitting strips or braces. In addition, it may be desirable to omit support strips, braces, and other structural members to improve endurance or durability, particularly in circumstances in which frequent extension and retraction of the retractable element 13 is expected. Support members and braces may also interfere with the clean lines of a retractable element 13 used as a display, creating an aesthetic undesirable to some users. Support members and braces may complicate the apparatus for winding and unwinding, just by their physical presence and size and weight, and they may add undesirable weight and cost. For example, with regard to weight, retractable element 13 comprising a polymeric substrate sheet and thin films may have a total weight less than 4 gm in the case of a polymeric substrate sheet having a 0.004 inch thickness deployed in a 7-inch display weighing around 3 gm and thin films comprising display layers weighing less than 1 gm. External bracing elements used with such a display may weigh many times more than this.

Endurance is provided so that the mean number of deployment cycles available in a retractable device before the device becomes damaged or degraded to the point of unacceptability to the user is high. Examples of unacceptability include failure to wind or unwind, scratching or other surface damage that degrades a displayed image, or kinks that create annoying distortions in a displayed image. The kinks may be a consequence of repeated dropping of the device, for example.

Device 10 may have various attributes that improve endurance, reduce size requirements, and provide various other features advantageous to particular applications. With respect to endurance, strong shear forces may be generated during extension and retraction of the retractable element 13. These shear forces may damage fragile substrate material that may be included in the retractable element 13. When a sheet material is bent to form a radius of curvature, the outer surface of the sheet will be in tension and the inner surface will be in compression. The tensile and compressive force vectors can be summed to create a resultant shear stress; the shear stress is proportional to sheet thickness and inversely proportional to the radius of curvature. Shear-induced damage to the retractable element 13 and/or external support structural member may appear only after repetitive screen deployments. Various materials-related and mechanical design features maybe implemented to support high endurance and long life, for example, of device 10. The retractable element 13 may be a single substrate to provide low winding torque, a small radius, and a compact rolled or otherwise retracted form. The retractable device may be thin to enable a small radius of curvature with low winding torque. Low winding torque may otherwise be achieved to improve device life and endurance. Using few or no external members to provide support for the retractable element 13 may provide endurance in terms of deployment cycles and a compact rolled or otherwise retracted form. The retractable element may be formed of materials selected to improve endurance. In one example, lubricity of films and the cylindrical enclosure is high to provide for low torque operation and lack of cracking with multiple bending cycles resulting in good fatigue performance. Wireless data communications may be employed to reduce the cabling requirement and increase the useful life of cable components. Avoiding the use of brushes and electrical wiper connections may result in lower maintenance and long operational life. Configurations that include limit stops and strain relief may also provide longer operational life.

Using such attributes in a device having a retractable element comprising a 7-inch display that is wound inside a cylinder enclosure of 0.375 inch diameter, a torque requirement less than 3 ounce-inches per inch of display width is achievable. Such a diameter is suitable for integrating with a smart phone having a similar thickness, for example. A sheet thickness in the range of 0.001-0.010 inches may provide adequate stability of the extended form, while requiring a small winding/unwinding torque. Using the wireless connection method, the number of signal conductors can be reduced from typically over twenty conductors, to as few as just two conductors required for power, with the transmission of display data handled by the wireless link. The small number of conductors can be implemented in a relatively narrow flexible interconnection circuit; the narrow circuit may be stressed less by the twisting action associated with winding and unwinding.

Portable devices will preferably endure dropping on the floor or other surface without substantial damage. In the extended mode, the retractable element 13 may fold on impact with the floor, thereby avoiding permanent damage. The absence of structural support members in the retractable element 13 of the device 10 may also provide a simpler and more durable structure for surviving stress of this type. The thinness of retractable element 13 may allow it to flex more easily and have less of a tendency to kink than thicker structures. The lower mass may also result in a lower momentum being developed during the fall, reducing the force on impact. In one embodiment, an accelerometer is provided in the device 10 to detect free-fall to provide information used to responsively partially or completely retract the retractable element 13 before the device 10 reaches the floor, for example, by activating a motorized or spring-loaded retraction mechanism.

In FIG. 1, host component 11 may comprise a processor (not shown) and memory (not shown). In the example of FIG. 1, the host component 11 is a smart phone configured to be held in a user's hand. The host computer 11 may comprise software or hardware applications and or electronic content that uses the retractable element 13 as an input and/or output mechanism or otherwise use or control retractable element 13. Applications and other electronic content execute or are otherwise used on the host component 11. As is known to one of skill in the art, such applications and content may be resident in any suitable computer-readable medium and execute on any suitable processor. For example, host device 11 may comprise a computer-readable medium such as a random access memory (RAM) coupled to a processor 11 that executes computer-executable program instructions and/or accesses information stored in memory. Such a processor may comprise a microprocessor, an ASIC, a state machine, or other processor, and can be any of a number of computer processors. Such a processor can comprise, or may be in communication with a computer-readable medium which stores instructions that, when executed by the processor, cause the processor to perform the steps described herein.

A computer-readable medium or other memory may comprise, but is not limited to, an electronic, optical, magnetic, or other storage device capable of providing a processor with computer-readable instructions. Other examples comprise, but are not limited to, a floppy disk, CD-ROM, DVD, magnetic disk, memory chip, ROM, RAM, an ASIC, a configured processor, optical storage, magnetic tape or other magnetic storage, or any other medium from which a computer processor can read instructions. The instructions may comprise processor-specific instructions generated by a compiler and/or an interpreter from code written in any suitable computer-programming language, including, for example, C, C++, C#, Visual Basic, Java, Python, Perl, and JavaScript.

The host component 11 may also comprise a number of external or internal devices such as a mouse, joystick, buttons, a touch screen, touch pad, a camera, a CD-ROM, DVD, a keyboard, a display, audio speakers, one or more microphones, or any other input or output devices. A bus may be included in the host component. Host component 11 could be a gaming device, a PDA or other portable computing devices, a laptop, a desktop computer, a workstation, a television, a cell phone, a smart phone, a video player, a music player, a medical device, and one of numerous other types of electronic devices. Host component 11 may be portable, stationary, used on a desktop, mounted to a wall or ceiling or otherwise used in a residence or other building, mounted or otherwise integrated in an automobile, boat, airplane, or other craft, or otherwise used.

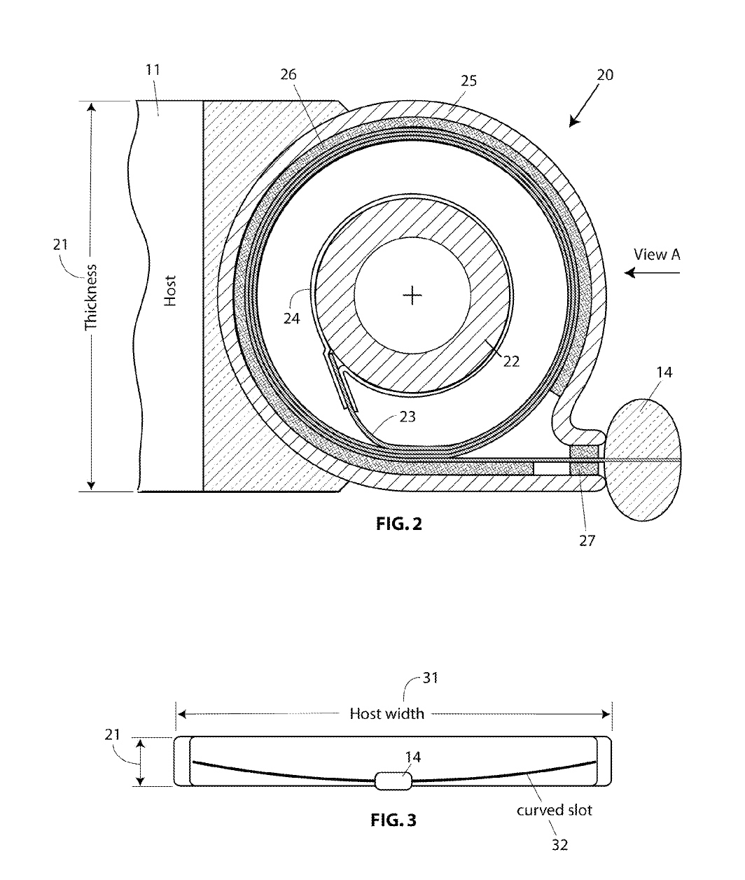

FIG. 2 is an expanded cross-sectional view of a portion of the device 10 of FIG. 1, in retracted form, and attached to host component 11. This configuration is referred to as “retracted form” as the extended portion of retractable element 13 (FIG. 1) is refracted and shown as substrate 23 within shell 25 of enclosure 12 such that only pull tab 14 is exposed. The overall thickness of mechanism 20 may be substantially consistent with thickness 21 of the host component 11, particularly if the device 10 is to be carried in a user's shirt pocket for example. Tubular shaft 22 is shown, and substrate 23 is attached to shaft 22 in a robust manner, such as by using adhesive tape 24. An alternative attachment method is to provide a tab feature (not shown) at the end of flexible substrate 23, insert it in a slit or narrow slot (not shown) in shaft 22, and optionally secure the end of the tab inside tubular shaft 22 using adhesive tape.

Substrate 23 (also referred to as “sheet”) may, but need not comprise, a polymeric material, a metallic material, or combinations thereof. The flexibility (and conversely the rigidity) of substrate 23 will depend on the chosen material(s) and its/their thickness. In one embodiment, the flexural modulus is in the range of 0.5-10 GPa. The thickness of substrate 23 will typically vary with the size of the deployed flexible device, and for certain devices is between 5 μm and 250 μm. Thinner substrates will pack more tightly into shell 25 of mechanism 20, and they will also be capable of a smaller radius of curvature. Stress in a curved substrate may be calculated by dividing the thickness of the substrate by the radius of curvature; if the thickness is reduced by half, the radius of curvature can also be reduced by half without increasing stress in the substrate material. The ability to retract the flexible device into a highly compact space may be desirable, for example, to reduce the thickness of shell 25 and device 10 to as small as 0.375 inch or smaller.

Winding forces associated with retraction and unwinding forces associated with extension depend on the stiffness of substrate 23; a stiffer substrate will typically require more torque on shaft 22 to accomplish the desired winding motion. Accordingly, it is desirable to use thin substrates that can be rolled into compact form and will require low torque in operation; for similar reasons it is also desirable to use thin films in fabricating the flexible device on the flexible substrate. Low torque requirements will typically be conducive to long life of mechanism 20. It may be desirable to configure a device to achieve an endurance target of an average of 10,000 deployment cycles, each cycle including winding and unwinding of substrate 23. However, if substrate 23 is too thin it will typically not be rigid enough to form a well-shaped display (having substantial uniformity) without drooping or sagging under the effect of gravity, or exhibiting other unwanted variations in shape or configuration. Also it may be desirable that the substrate support the application of finger movements or gestures for the case of touch-sensitive displays. The advantages of using a thin substrate as well as other advantages are enabled by stiffening the deployed screen 13 of FIG. 1 using an arcuate cross-sectional shape imposed on substrate 23, to be further described in reference to FIG. 3. In the retracted position, the substrate can be substantially flattened against the winding surface to provide a compact shape in the retracted form. As described below, in the extended position, the cross-section of the substrate 23 can vary from flat to provide mechanical rigidity.

In FIG. 2 it can also be seen that substrate 23 is coiled at the maximum available radius, i.e. in the outer regions of the available air space; this is a consequence of the inherent stiffness of substrate 23. Low friction between coiled layers of substrate 23 will assist in allowing this desired shape to be repeatedly accomplished over many deployment cycles, as well as reducing the required winding torque. Accordingly dry lubricants such as graphite powder may be used to reduce friction between the coiled layers. Also friction between substrate 23 and shell 25 may be reduced using a low friction material 26 as shown. The low friction material or surface may comprise, but is not limited to, PTFE or a fibrous material such as felt or velvet. Alternatively, shell 25 may include a filler having lubricious properties; an example of such a filler material is silicone oil. Another lubricious material developed for non-stick and low friction contact with polymeric materials is NEDOX SF2 developed by General Magnaplate Corporation, and is suitable in rollable devices. Notwithstanding attempts to reduce friction, both the extended form and the retracted form may be mechanically stable and not require a brake to maintain either configuration. In the retracted form, stability is created by residual friction between the layers that will typically prevent unwanted uncoiling of the stored substrate 23. Because bending forces are released during extension, the extended form is a lower energy configuration than the retracted form, and it too will typically be mechanically stable, not requiring a brake to maintain the extended form during use. Cleaning pads 27 are provided to wipe any dirt or particulates off of substrate 23 during the retraction process, thus reducing the accumulation of contaminants inside shell 25. The physical size of pull tab 14 compared with the gap dimension at the shell 25 opening provides a limit stop adjacent pads 27, signaling to the user or to the winding mechanism that the retraction cycle is complete.

FIG. 3 is an end view of retractable mechanism 20, shown as “View A” in FIG. 2. The width of mechanism 20 is shown as equal to host width 31, although retractable mechanism 20 may have a different width than host component 11. For example, mechanism 20 may be wider than host width 31, and still fit comfortably in a user's shirt pocket for example. Pull tab 14 is shown. Curved slot 32 may be used to impose the desired arcuate cross-sectional shape on substrate 23 as it is withdrawn from enclosure 12 to form the extended form of display screen 13, as shown in FIG. 1. The desired arcuate cross-sectional shape may also be imposed on substrate 23 using heat forming, or a casting mold as examples. The heat forming may be vacuum forming or compression forming, each providing a combination of heat and pressure. The radius of curvature of slot 32 is the same as the desired arcuate cross-sectional radius of curvature, also referred to as the stiffening radius of curvature. This radius of curvature may be imposed and determined at slot 32; for an extended screen or other flexible device it may vary with distance from slot 32. Other arcuate forms may be used. The radius of curvature of the curved slot can vary over a range, for example, between 0.5 inch and 20 inches, for example, 10 inches. They may comprise curvature or an angled form applied only at the edges or any other specific portion or potions of substrate 23. They may comprise complex curves, rather than a single radius of curvature. The curvature may vary in both the longitudinal and transverse directions of the extended display screen. The desired curvature may be reinforced at the remote end of the extended display by an edge feature such as a right-angled sidewall (not shown). In this case, imposition of the desired curvature may be reinforced by the right-angled sidewall.

In some implementations, the extended portion can be characterized by one or more radii of curvature. In some embodiments, the extended portion is characterized by a plurality of radii of curvature. In these implementations, rather than a single curvature across the substrate 32, the cross section can be characterized by several curvatures as a function of position, for example, flat in a central region (substantially an infinite radius of curvature) or a gentle curvature in the central region and a smaller radius of curvature at edge portions. In some embodiments, the central region is flat and peripheral portions (e.g., sides) have edges that are either flat angled portions or curved angled portions. The curvature can vary at the transition from the flat region to the angled edges to provide mechanical rigidity. One of ordinary skill in the art would recognize many variations, modifications, and alternatives.

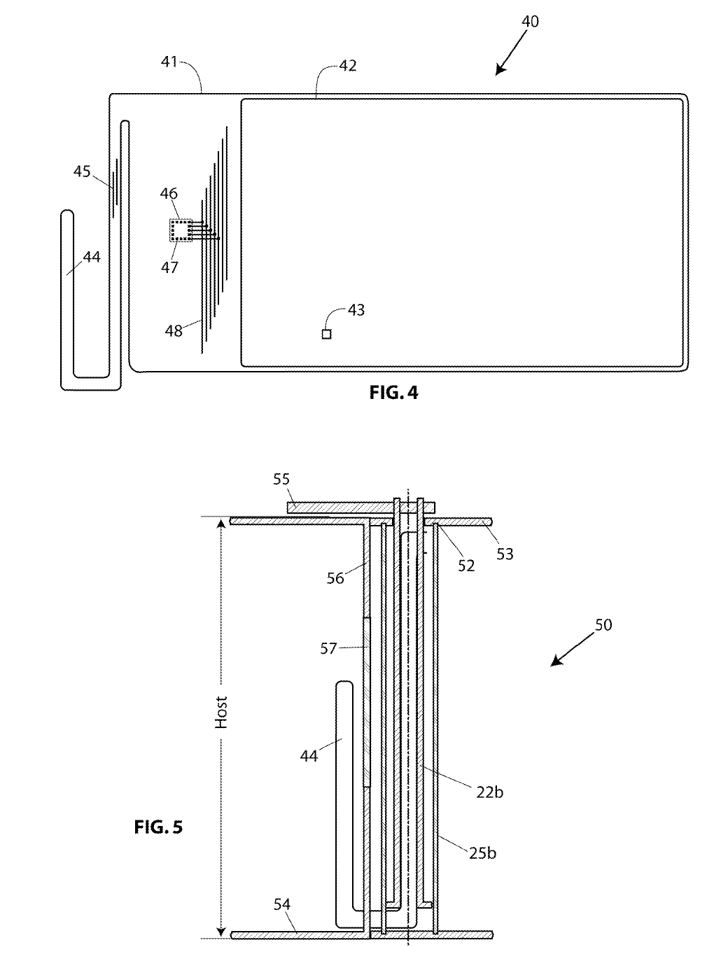

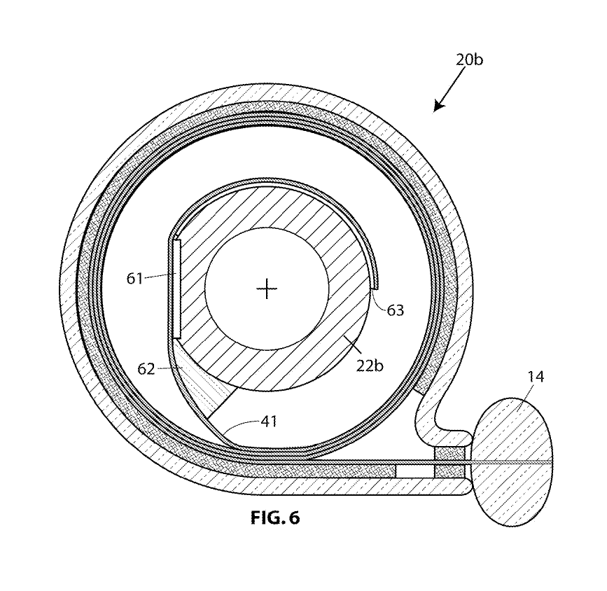

FIG. 4 is a top schematic view of a flexible circuit 40 used in a retractable mechanism. Base substrate 41 is a specialized version of flexible substrate 23 of FIG. 2, wherein substrate 41 is configured to support an interface chip for interfacing between a host processor and a display screen for example. Base substrate 41 in this example is a thin polymeric sheet. Active display area 42 is shown, comprising a plurality of pixels. A single pixel 43 is illustrated but it will be understood that numerous pixels may be used throughout the surface of the active display area 42. The active display area 42 may be created using thin films. Each pixel is capable of emitting or reflecting light and has associated display circuits (not shown). Pigtail 44 may be thread-able through a shaft assembly to be described in reference to FIG. 5, terminating in the host enclosure where it can be connected with a host power source (not shown). Conductive traces 45 are shown for delivering power or signals using pigtail 44. Chip site 46 is shown with input/output pads 47, in preparation for attachment of a wireless interface chip for example, to be further described in reference to FIG. 6. The interface chip in this example provides an active matrix (AM) interface, including row and column drivers to the pixel array, with data rates supporting video for movies or television, for example. A passive matrix (PM) interface may also be used. Conductive traces 48 are shown, representing interconnection circuits between the wireless chip and the display circuits associated with the pixels. For example, the display circuits may include TFTs at each pixel site, plus light emitting circuits such as light emitting diodes (LEDs), and may also implement a row and column addressing scheme. The LEDs may be organic (OLEDs) or quantum dot (QLEDs) for example.

FIG. 5 is a cross-sectional view of shaft assembly 50 of a device. Shell 25b is shown, similar to shell 25 of FIG. 2, comprised, this embodiment, of a non-metallic material to avoid shielding the desired radio waves used in communication between the host processor and the display screen. Shell 25b may be supported at each end in a wall 53 of an enclosure 12 (FIG. 1). Tubular shaft 22b is shown, similar to shaft 22 of FIG. 2, but adapted to accept the wireless chip, to be further described in reference to FIG. 6. Pigtail 44 is preferably threaded through slots (not shown) in tubular shaft 22b and shell 25b and end wall 56 of host enclosure 54, so as to provide an end accessible to the interior of the host. Hand crank 55 is shown as one of many possible mechanisms for providing torque to wind flexible substrate 41 around shaft 22b. End wall 56 of the host, for example host 11, is provided with a non-metallic window 57, again to avoid shielding desired radio waves. During winding and unwinding of flexible circuit 40, several rotations of shaft 22b will typically be required. In order to limit the maximum degree of flexing required in pigtail 44 during operation, the assembly process may include a pre-twisting step in the reverse direction, in the amount of one half of the rotation required for deployment.

FIG. 6 is an expanded cross-sectional view of retractable mechanism 20b showing placement of a wireless chip 61 for interfacing between a host processor and display circuits, for example. The wireless chip 61 may implement a near field communication (NFC) standard, as is known in the art. Mechanism 20b could be a stand-alone device as shown, if a battery were included to power chip 61. A recess is shown in tubular shaft 22b for accepting chip 61; a similar recess could also be used to accommodate a battery, if required, or the battery could be integrated with pull tab 14 for example. Wireless chip 61 may be bumped with gold or copper stud bumps, for example, to assist in making electrical connections with pads 47 on substrate 41. Alternatively, an anisotropic conductive film, ACF, (not shown) may be provided for making connections between wireless chip 61 and flexible substrate 41. During assembly of retractable mechanism 20b, pads 47 of FIG. 4 are aligned with features on chip 61, and flexible substrate 41 is pressed against chip 61 and robustly attached to shaft 22b, for example, using a wedge of adhesive-coated foam 62 plus adhesive tape 63. Wedge 62 may provide strain relief as the extended display becomes fully deployed; this end point can be detected by the user or the extension mechanism in a manner that supports gentle handling of the fragile substrate, contributing to long life of the mechanism. During assembly of chip 61 with substrate 41 uniform pressure may be applied to deform the stud bumps or compress the ACF to make robust electrical contacts with corresponding pads 47.

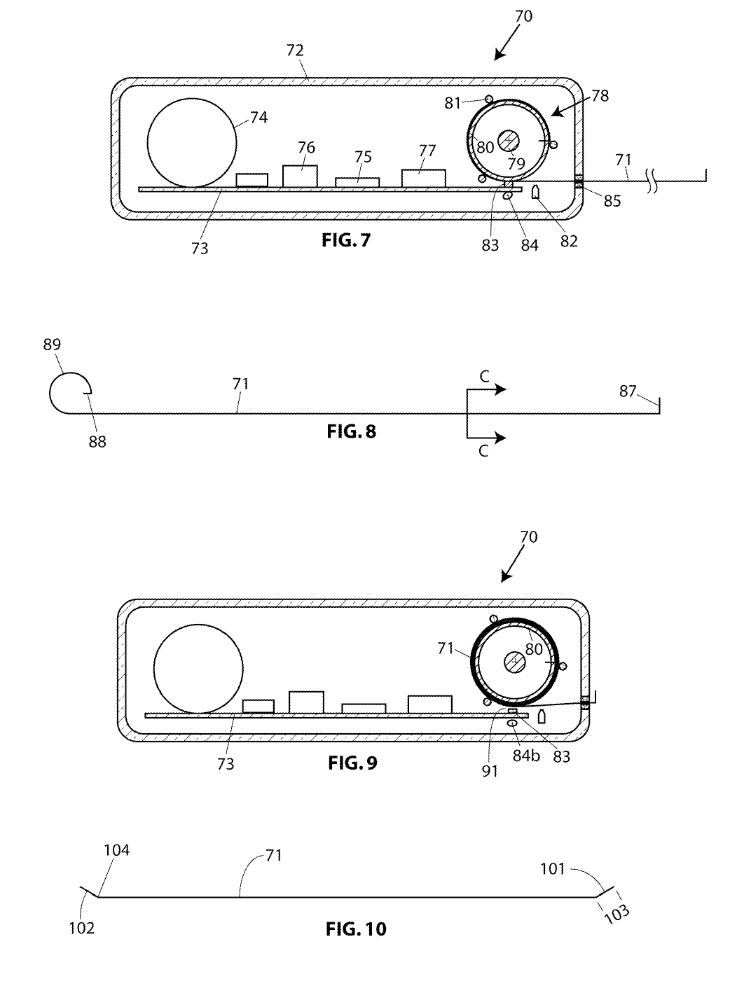

FIG. 7 illustrates an electronic device 70 having a flexible retractable element 71. Device 70 includes an enclosure 72, a printed circuit board (PCB) 73, a battery 74, a microprocessor 75, memory circuits 76, and a display controller 77. Other devices such as a touch screen controller, accelerometer, gyroscope, and the like may be included on PCB 73. A drum motor 78 is shown, preferably including gearing (not shown) between fixed shaft 79 and rotatable sleeve 80. A set of spring-mounted rollers 81 is provided around the periphery of sleeve 80, to retain retractable element 71 as it is rolled and unrolled (wound and unwound). A location sensor 82 is shown, for sensing an alignment mark (not shown) on retractable element 71. A compliant and electrically conductive contact pad 83 is shown, connecting between contact pads (not shown) on retractable element 71 and corresponding contact pads (not shown) on PCB 73; this connectivity applies when retractable element 71 is in extended form as shown, and is used for conveying signals and power to the retractable element. The connectivity is engaged using a cam mechanism 84 controlled by microprocessor 75. Cleaning pads 85 are also shown for wiping contaminants from retractable element 71 as it is retracted inside enclosure 72.

FIG. 8 shows a form of retractable element 71 in an embodiment. A first right-angle element 87 is provided to reinforce the desired shape of element 71, and also to provide a means for a user to pull element 71 out of device 70 for use. A second right-angle element 88 is provided for assisting to capture element 71 with rotatable sleeve 80 of FIG. 7; the capture configuration utilizes both element 88 and a curved portion 89 of retractable element 71. This capture arrangement involves a simple operation of snapping retractable element 71 into place, using curved portion 89 and capturing second right-angle element 88 in a slot (not shown) provided in rotatable sleeve 80 of FIG. 7. Such a simple capture arrangement may be convenient for replacing a retractable device if it becomes worn with use or otherwise degraded for example. A lip roller may be used to form curved portion 89 of retractable element 71, for example.

FIG. 9 is a schematic diagram illustrating electronic device 70 in retracted form. Retractable element 71 has been coiled around rotatable sleeve 80 as shown. Contact pad 83 no longer provides electrical continuity between corresponding contact points on PCB 73 and retractable element 71; an air gap 91 is shown. Cam mechanism 84 has been rotated into the disengaged or neutral position, 84b.

FIG. 10 shows a cross-section of retractable element 71 corresponding to section CC of FIG. 8. In this case the arcuate form of retractable element 71 comprises angled side-edges 101 and 102. Side-edges are illustrated as the edges parallel to the direction in which retractable element 71 is extended. Angled side edges 101 and 102 typically are provided at an angle between 30 and 60 degrees to the center region of element 71, depending on the degree of stiffness required. If the angle is too large, this may create difficulty in winding element 71 around rotatable sleeve 80 even although element 71 will typically flatten as it is rolled up, and may also accelerate fatigue failure at the junction 104 of the angled side-edge with the center portion of element 71. Similarly, the length dimension 103 of an angled side-edge 101 may vary between typically 2 mm and 20 mm, depending on the overall size of retractable element 71, and the degree of stiffness desired. Angled side-edges such as shown in FIG. 10 may be easier to fabricate, providing benefits associated with the illustrated embodiment.

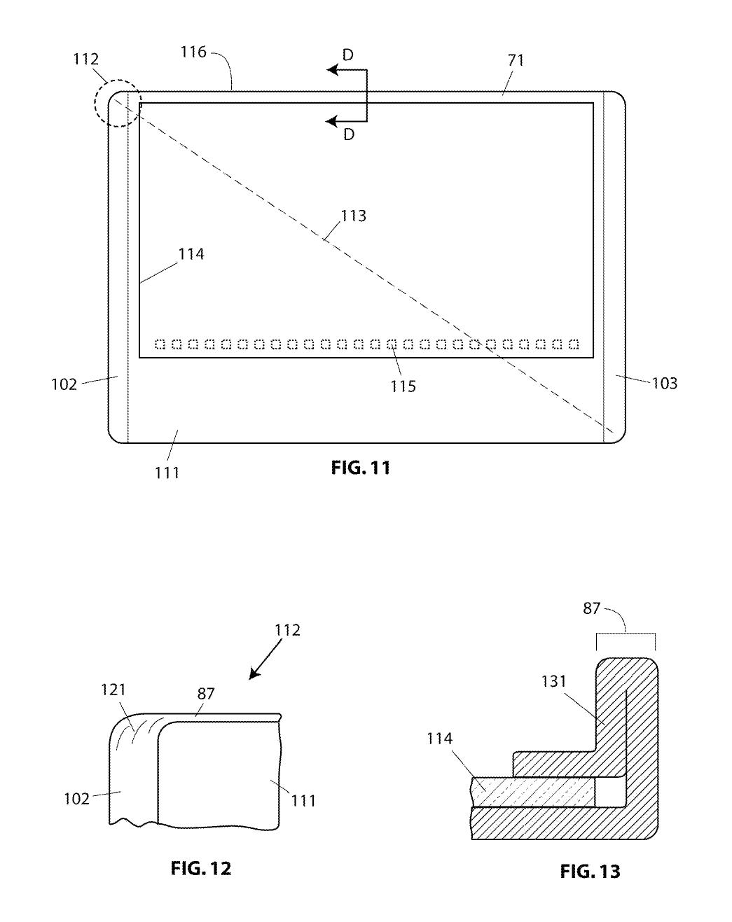

FIG. 11 is a schematic top view of retractable element 71 described in reference to FIGS. 7-10. A center flat region 111 is shown, also angled side-edges 102 and 103. First right-angle 87 and second right-angle 88 of FIG. 8 are not apparent in FIG. 11, because they are typically too thin to show. Corner region 112 shows a gradual transition from right-angle edges 87, 88 to side-edges 102, 103, and this gradual transition provides corner strength in retractable element 71, to be further described in reference to FIG. 12. This corner strength provides additional mechanical stability in retractable element 71; in particular it helps to overcome an undesirable tendency for element 71 to fold along a diagonal such as 113. A pixel display substrate 114 is shown attached to retractable element 71. On the back side of display substrate 114 contact regions 115 are shown, and retractable element 71 is adapted with holes as required to allow electrical connection, such as through contact pads 83 described in reference to FIG. 7, to corresponding contact points provided on a PCB such as 73 of FIG. 7 for example. These corresponding contact points allow electrical signals from a display controller such as 77 in FIG. 7 to be transmitted and then converted to a visual image on pixel display 114 for example. The leading edge 116 of retractable element 71 is shown.

FIG. 12 is an expanded view of corner region 112 of FIG. 11. The flat center region 111 of retractable element 71 is shown, along with first right-angle element 87 and angled side-edge 102. A gradual transition from vertical element 87 to angled element 102 is indicated by the contour lines 121. This gradual transition provides corner strength that improves the mechanical strength and stability of retractable element 71 in extended form.

FIG. 13 is an expanded view of leading edge 116 of retractable element 71, described in reference to FIG. 11. Folded substrate material 131 of element 71 provides a strengthened first right-angle member 87, thereby providing a convenient feature that a user may pull to extend element 71. The folded portions of element 71 can also effectively grip an edge of pixel display substrate 114 as shown, providing a convenient and low cost method of attachment. Particularly for the case of a metallic substrate, the folding of element 71 may be achieved by cold forming as previously described, with the benefit that sensitive circuits that may be present on attached transducer element 114 will not be adversely affected. By gripping element 114 at an edge as shown, rather than bonding the entire surface of element 114 to element 71, elements 71 and 114 will act somewhat independently during winding and unwinding operations, thereby reducing shear stress and enabling a lower torque to be used. In order to maintain integrity of the attachment of element 114 to element 71 near contact pads 115, an elastic adhesive (not shown) is preferably used in this region, enabling the somewhat independent behavior of the two components during winding and unwinding.

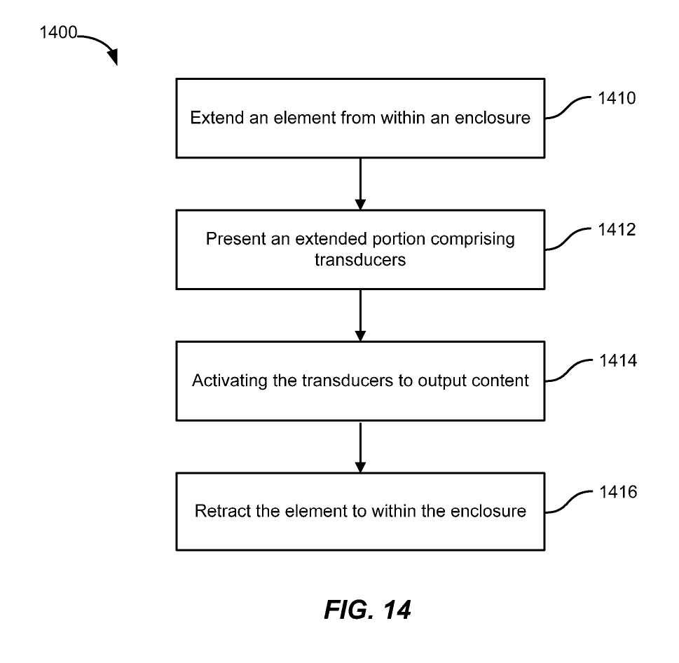

FIG. 14 is a simplified flowchart illustrating a method of operating a retractable electronic device according to an embodiment of the present invention. The method includes extending an element from within an enclosure (1410). The method also includes presenting an extended portion comprising transducers outside of the enclosure (1412). Extending the element from within the enclosure can include extending the element through a curved slot in the enclosure. In the extended position, the element can be characterized by an arcuate cross-sectional shape, a flat central portion and angled side-edges, or combinations thereof.

The method also includes activating the transducers to output content via a surface of the extended portion of the element (1414) and retracting the element to a compact form within the enclosure (1416). In some embodiments, activating the transducers can include receiving input via a surface of the extended portion of the element.

It should be appreciated that the specific steps illustrated in FIG. 14 provide a particular method of operating a retractable electronic device according to an embodiment of the present invention. Other sequences of steps may also be performed according to alternative embodiments. For example, alternative embodiments of the present invention may perform the steps outlined above in a different order. Moreover, the individual steps illustrated in FIG. 14 may include multiple sub-steps that may be performed in various sequences as appropriate to the individual step. Furthermore, additional steps may be added or removed depending on the particular applications. One of ordinary skill in the art would recognize many variations, modifications, and alternatives.

Numerous specific details are set forth herein to provide a thorough understanding of the claimed subject matter. However, those skilled in the art will understand that the claimed subject matter may be practiced without these specific details. Other elements that would be known by one of ordinary skill have not been described in detail so as not to obscure claimed subject matter. The use of “adapted to” or “configured to” herein is meant as open and inclusive language that does not foreclose devices adapted to or configured to perform additional tasks or steps.

The devices and systems discussed herein are not limited to any particular hardware architecture or configuration. An electronic or other computing device can include any suitable arrangement of components. Computing devices include but are not limited to multipurpose microprocessor-based computer systems accessing stored software that programs or configures the computing system from a general purpose computing apparatus to a specialized computing apparatus. Any suitable programming, scripting, or other type of language or combinations of languages may be used to implement software to be used in programming or configuring a computing device, for example, to control operation of a retractable element, contents to be displayed on a retractable element, or process input received from an input mechanism provided on a retractable element.

While the present subject matter has been described in detail with respect to specific embodiments thereof, it will be appreciated that those skilled in the art, upon attaining an understanding of the foregoing may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art. For example, a pull tab 14 is shown for extending (unwinding) an exemplary display screen and a hand crank is shown for retracting (winding) the display screen, but winding and unwinding may be accomplished using other means, including but not limited to any combination of human fingers, a knurled knob, a hand crank, a spring, and a motor, as is known in the art. Similarly, while an example of a retractable mechanism attached to a smart phone is described, a retractable element and/or an associated enclosure may be separated from the smart phone or other host and need not be used with a host at all. For example, a retractable screen for viewing a projected image could be a stand-alone device, not requiring any power or associated wires. Also, the principles described for the retractable display may be applied to larger and smaller display formats, for example a device having a retractable display for viewing large format X-ray images or a miniaturized retractable device attached to eye glasses. A device need not be portable. The retractable device may not be a display but rather a keyboard, or a speaker for creating sound, or may implement another transducer or heating/cooling device, or any other useful flexible device having an extended form and a retracted form.

What is claimed is:

1. A device comprising:
a processor;
a memory coupled to the processor, wherein the memory is encoded with instructions that are executable by the processor to provide content signals; and
a display screen extendable to present an extended portion comprising display pixels configured to display content using the content signals, wherein extension of the display screen imposes a compound shape on the extended portion of the display screen characterized by a central region and a peripheral angled edge region.

2. The device of claim 1 wherein the central region comprises at least one of a flat region or a curved region.

3. The device of claim 1 wherein the extended portion further comprises touch sensors for receiving touch input on a surface of the extended portion.

4. The device of claim 1 further comprising an enclosure having at least one of a curved slot or a straight slot from which the extended portion extends while extended.

5. The device of claim 4 wherein the display screen is secured within the enclosure in a retracted position, wherein the display screen is substantially flattened against a winding surface while secured within the enclosure.

6. The device of claim 4 further comprising a tab accessible for extending the display screen from the enclosure.

7. The device of claim 4 further comprising a crank, wherein rotation of the crank winds the display screen within the enclosure.

8. The device of claim 1 wherein each of the display pixels comprises display circuits operable to emit or reflect light, wherein the display circuits are coupled to the processor.

9. The device of claim 8 further comprising wires or conductive traces coupling the display circuits to the processor.

10. The device of claim 8 further comprising an interface chip operable to provide for wireless communications under the control of the processor.

11. The device of claim 1 wherein the display screen comprises a polymeric material having a thickness between 5 μm and 250 μm.

12. The device of claim 1 wherein the display screen comprises a metallic material having a thickness between 5 μm and 250 μm.

13. The device of claim 1 wherein, when fully extended, the extended portion has a length to width ratio between 0.1 and 10.

14. The device of claim 1 further comprising at least one of a motor or a spring configured to retract the display screen.

15. A device comprising:
an enclosure; and
an element extendable from the enclosure to present an extended portion comprising transducers, wherein the extended portion is characterized by a plurality of radii of curvature.

16. The device of claim 15 wherein the enclosure comprises a curved slot having an arcuate cross-sectional shape.

17. The device of claim 15 wherein the transducers convert electrical signals originating from a processor to display a pixel-based electronic image.

18. The device of claim 15 wherein the transducers convert touch input on a surface of the extended portion to signals provided to a processor.

19. The device of claim 15 wherein the transducers produce sound, heat, or cooling.

20. A method of operating a retractable electronic device, the method comprising:
extending an element from within an enclosure to present an extended portion comprising transducers outside of the enclosure;
activating the transducers to output content via a surface of the extended portion of the element; and
retracting the element to a compact form within the enclosure.

21. The method of claim 20 wherein extending the element from within the enclosure comprises extending the element through a curved slot in the enclosure.

22. The method of claim 20 wherein the extended portion is characterized by an arcuate cross-sectional shape.

23. The method of claim 20 wherein the extended portion is characterized by a flat central portion and angled side-edges.

24. The method of claim 20 wherein activating the transducers comprises receiving input via a surface of the extended portion of the element.
